(19) United States
(12) Patent Application Publication
(10) Pub. No.: US 2026/0215330 A1
(43) Pub. Date: Jul. 23, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Yu FUKUNAGA, Tokyo (JP); Tatsuki ONOMATA, Tokyo (JP)

(73) Assignee: Mitsubishi Electric Corporation, Tokyo (JP)

(21) Appl. No.: 19/404,542

(22) Filed: Dec. 1, 2025

(30) Foreign Application Priority Data
Jan. 20, 2025 (JP) 2025-007449

(51) Int. Cl. H10W 76/12; H10W 76/01

(52) U.S. Cl. CPC H10W 76/165; H10W 76/01

(57) ABSTRACT

An object is to provide a technology that can enhance thermal dissipation of a semiconductor device. The semiconductor device includes: a cap nut having an upper portion with an opening, the cap nut being buried in an upper surface of a sidewall of a case except the upper portion; and an electrode including a first edge that is closer to a semiconductor element and is electrically connected to the semiconductor element, a second edge integrated into the upper portion of the cap nut, and a middle portion bent stepwise between the first edge and the second edge, the middle portion being buried in the case, wherein the cap nut and the electrode are higher in thermal conductivity than copper.

### BACKGROUND

### Technical Field

The present disclosure relates to a semiconductor device and a method of manufacturing the semiconductor device.

### Description of the Background Art

A technology of integrating a cap nut hexagonal in a plan view into an electrode bent in advance and then forming, by insert molding, a case into which the electrode is to be buried has been proposed as a method of manufacturing a semiconductor device such as a semiconductor module (e.g., Japanese Patent Application Laid-Open No. 2012-222009). Such a technology allows the electrode to be appropriately and easily bent before the insert molding, even when the electrode is thick.

However, thermal dissipation of the semiconductor device formed in the aforementioned manner is susceptible to improvement.

### SUMMARY

The present disclosure has been made in view of the problem, and has an object of providing a technology that can enhance thermal dissipation of a semiconductor device.

A semiconductor device according to the present disclosure includes: a semiconductor element; a case having a sidewall surrounding a lateral side of the semiconductor element; a cap nut having an upper portion with an opening, the cap nut being buried in an upper surface of the sidewall except the upper portion; and an electrode including a first edge that is closer to the semiconductor element and is electrically connected to the semiconductor element, a second edge integrated into the upper portion of the cap nut, and a middle portion bent stepwise between the first edge and the second edge, the middle portion being buried in the case, wherein the cap nut and the electrode are higher in thermal conductivity than copper.

The thermal dissipation of the semiconductor device can be enhanced.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a structure of a semiconductor module according to Embodiment 1;

FIG. 2 is a cross-sectional view illustrating a structure of a semiconductor module according to Embodiment 2; and

FIG. 3 is a plan view illustrating the structure of the semiconductor module according to Embodiment 2.

### DESCRIPTION OF THE PREFERRED EMBODIMENTS

Embodiments will be described with reference to the attached drawings. The features to be described in Embodiments below are exemplifications, and all of the features are not necessarily essential. In the description below, identical constituent elements in a plurality of Embodiments will be denoted by the same or similar reference numerals, and different constituent elements will be mainly described. In the following description, a particular position and a particular direction such as “up”, “down”, “left”, “right”, “front”, or “back” need not always coincide with an actual position and an actual direction.

### Embodiment 1

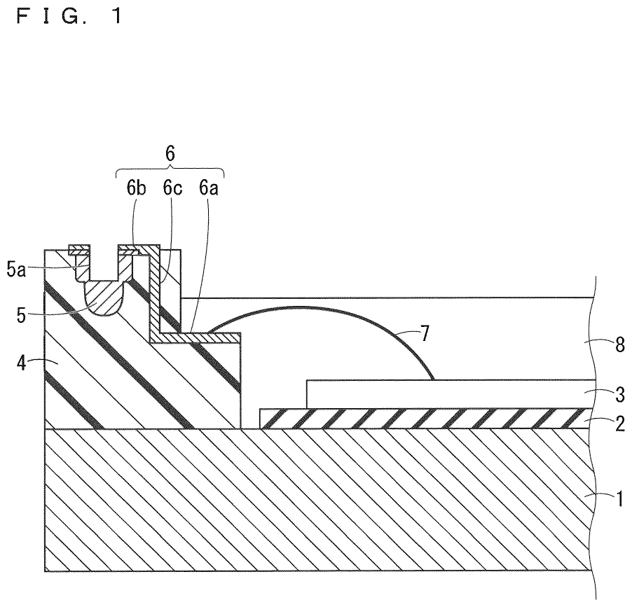

FIG. 1 is a cross-sectional view illustrating a structure of a semiconductor module that is a semiconductor device according to Embodiment 1. The semiconductor module in FIG. 1 includes a metal base plate 1, an insulating substrate 2, a semiconductor element 3, a case 4, a cap nut 5, an electrode 6, a wire 7, and a sealant 8.

The metal base plate 1 is made of, for example, copper. The insulating substrate 2 is provided on the metal base plate 1, and is made of, for example, ceramics. The insulating substrate 2 may be an insulating layer. Metal patterns that are not illustrated are provided on both sides of the insulating substrate 2.

The semiconductor element 3 is provided on the metal pattern on an upper surface of the insulating substrate 2. The metal base plate 1 and the metal pattern on a lower surface of the insulating substrate 2 are bonded through, for example, a bonding material that is not illustrated. The metal pattern on the upper surface of the insulating substrate 2 and the semiconductor element 3 are bonded through, for example, a bonding material that is not illustrated. For example, solder or a sintered material is used as the bonding material.

The semiconductor element 3 is, for example, a metal-oxide-semiconductor field effect transistor (MOSFET), an insulated-gate bipolar transistor (IGBT), a reverse-conducting IGBT (RC-IGBT), a Schottky barrier diode (SBD), or a PN junction diode (PND). The semiconductor element 3 may be made of normal silicon (Si), or a wide bandgap semiconductor such as silicon carbide (SiC), gallium nitride (GaN), gallium oxide (Ga₂O₃), or diamond. When the semiconductor element 3 is made of the wide bandgap semiconductor, the semiconductor element 3 can perform stable operations at high temperatures and high voltages, and accelerate the switching speed.

The case 4 has a sidewall surrounding a lateral side of the semiconductor element while being integrated into the metal base plate 1. The case 4 and the sidewall are substantially the same in Embodiment 1. The case 4 is made of, for example, a thermoplastic resin such as polyphenylene sulfide (PPS).

The cap nut 5 includes an upper portion with an opening 5a such as a screw hole, and a lower portion without any opening in communication with the opening 5a. The cap nut 5 is buried in the upper surface of the case 4 except the upper portion on the opening 5a side. The shape of the cap nut 5 is, for example, hexagonal in a plan view.

The electrode 6 includes a first edge 6a, a second edge 6b, and a middle portion 6c. The first edge 6a is an edge that is closer to the semiconductor element 3 and is electrically connected to the semiconductor element 3. The first edge 6a is electrically connected to the semiconductor element 3 through the wire 7 in Embodiment 1, which is not limited to this.

The second edge 6b is integrated into an upper portion of the cap nut 5 by, for example, welding. The middle portion 6c between the first edge 6a and the second edge 6b is bent stepwise between the first edge 6a and the second edge 6b, and is buried in the case 4. The electrode 6 has an approximately Z shape by being bent stepwise in a cross-sectional view.

The sealant 8 is provided in a space surrounded by the metal base plate 1 and the case 4. The sealant 8 is made of, for example, an epoxy resin. An upper portion of the sealant 8 may be covered with a lid that is provided on the case 4 and is not illustrated.

In the aforementioned structure, the cap nut 5 and the electrode 6 are higher in thermal conductivity than copper. The cap nut 5 and the electrode 6 may be made of, for example, an alloy of copper and silver, or include a body made of copper and a plating film made of silver provided on a surface of the body. Since such a structure can enhance thermal dissipation of the cap nut 5 and the electrode 6, and even of the semiconductor element 3 in the semiconductor module, a range of voltages to be used in the semiconductor element 3 can be widened.

When the cap nut 5 and the electrode 6 are made of an alloy of copper and silver, setting a ratio of silver in the alloy to 1% or higher and 10% or lower is favorable in view of suppressing an increase in the cost. When the cap nut 5 and the electrode 6 include a plating film made of silver, not only thermal dissipation of the semiconductor module can be enhanced, but also corrosion of the cap nut 5 and the electrode 6 can be suppressed more than those including a plating film made of typical nickel.

Next, a method of manufacturing the semiconductor module according to Embodiment 1 will be simply described. First, a first step of integrating the cap nut 5 with the first edge 6a of the electrode 6 is performed. Next, a second step of bending stepwise the middle portion 6c of the electrode 6 between the first edge 6a and the second edge 6b of the electrode 6 is performed. The first step may be performed after the second step. Then, after the first step and the second step, a third step of insert molding with a thermoplastic resin to be the case 4 being prevented from flowing into the opening 5a of the cap nut 5 is performed. In this insert molding, for example, the thermoplastic resin to be the case 4 is caused to flow from the lower portion of the cap nut 5 into a mold, so that the lower portion of the cap nut 5 without any opening in communication with the opening 5a prevents the thermoplastic resin from flowing into the opening 5a.

Since such a manufacturing method prevents flow of the thermoplastic resin into the opening 5a of the cap nut 5, the manufacturing cost of the case 4 can be reduced. Even when the electrode 6 is thick, since the electrode 6 can be appropriately and easily bent before the insert molding, the bending standard of the electrode 6 can be easily satisfied.

### Embodiment 2

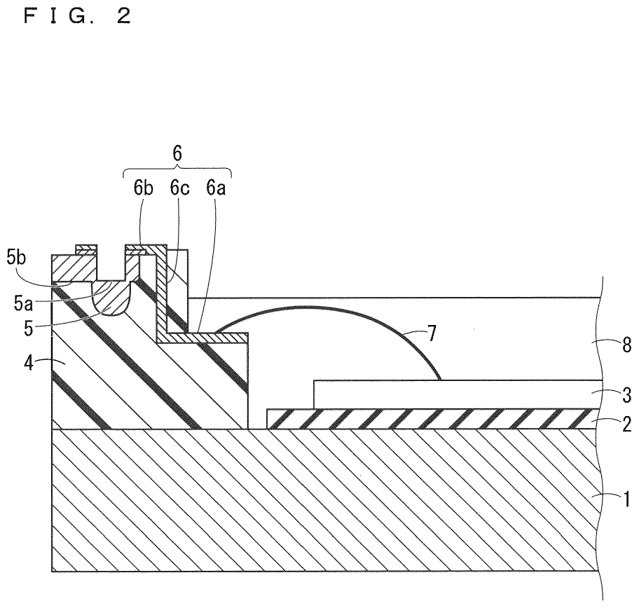

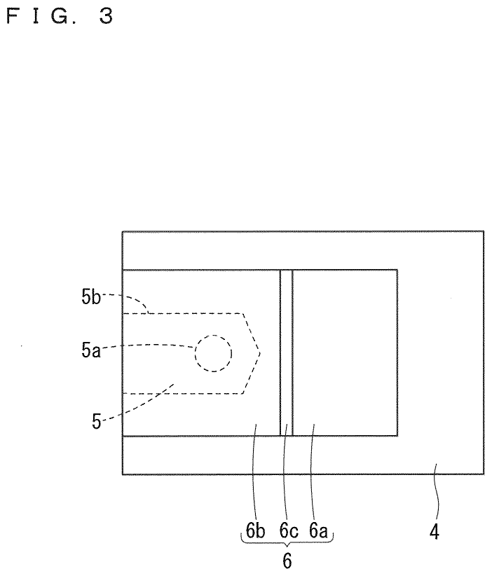

FIG. 2 is a cross-sectional view illustrating a structure of a semiconductor module that is a semiconductor device according to Embodiment 2. FIG. 3 is a plan view illustrating the structure. In Embodiment 2, the cap nut 5 includes a portion 5b exposed from a lateral surface of the case 4. Such a structure can further enhance thermal dissipation of the cap nut 5 and the electrode 6, and even of the semiconductor element 3 in the semiconductor module. While the portion 5b of the cap nut 5 extends from the opening 5a of the cap nut 5 toward the lateral surface of the case 4 in the example of FIG. 3, the portion 5b need not extend.

In the present disclosure in English, “a” and “an” mean more than one. Thus, “a”, “an”, “one or more”, and “at least one” can be used for the same meaning.

Embodiments and its modifications can be freely combined, or appropriately modified and omitted.

A summary of various aspects of the present disclosure will be hereinafter described as Appendixes.

### (Appendix 1)

A semiconductor device, comprising:
a semiconductor element;
a case having a sidewall surrounding a lateral side of the semiconductor element; a cap nut having an upper portion with an opening, the cap nut being buried in an upper surface of the sidewall except the upper portion; and
an electrode including a first edge that is closer to the semiconductor element and is electrically connected to the semiconductor element, a second edge integrated into the upper portion of the cap nut, and a middle portion bent stepwise between the first edge and the second edge, the middle portion being buried in the case,
wherein the cap nut and the electrode are higher in thermal conductivity than copper.

### (Appendix 2)

The semiconductor device according to appendix 1,
wherein the cap nut includes a portion exposed from a lateral surface of the sidewall.

### (Appendix 3)

The semiconductor device according to appendix 2,
wherein the portion of the cap nut extends from the opening of the cap nut toward the lateral surface of the sidewall.

### (Appendix 4)

A method of manufacturing the semiconductor device according to any one of appendixes 1 to 3, the method comprising the steps of:
integrating the cap nut into the first edge of the electrode;
bending the middle portion stepwise between the first edge and the second edge; and
insert molding with a resin to be the case being prevented from flowing into the opening of the cap nut after the integrating and the bending.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor element;
a case having a sidewall surrounding a lateral side of the semiconductor element;
a cap nut having an upper portion with an opening, the cap nut being buried in an upper surface of the sidewall except the upper portion; and
an electrode including a first edge that is closer to the semiconductor element and is electrically connected to the semiconductor element, a second edge integrated into the upper portion of the cap nut, and a middle portion bent stepwise between the first edge and the second edge, the middle portion being buried in the case,
wherein the cap nut and the electrode are higher in thermal conductivity than copper.

2. The semiconductor device according to claim 1,
wherein the cap nut includes a portion exposed from a lateral surface of the sidewall.

3. The semiconductor device according to claim 2,
wherein the portion of the cap nut extends from the opening of the cap nut toward the lateral surface of the sidewall.

4. A method of manufacturing the semiconductor device according to claim 1, the method comprising:
integrating the cap nut into the first edge of the electrode;
bending the middle portion stepwise between the first edge and the second edge; and
insert molding with a resin to be the case being prevented from flowing into the opening of the cap nut after the integrating and the bending.

5. A method of manufacturing the semiconductor device according to claim 2, the method comprising:
integrating the cap nut into the first edge of the electrode;
bending the middle portion stepwise between the first edge and the second edge; and
insert molding with a resin to be the case being prevented from flowing into the opening of the cap nut after the integrating and the bending.

6. A method of manufacturing the semiconductor device according to claim 3, the method comprising:
integrating the cap nut into the first edge of the electrode;
bending the middle portion stepwise between the first edge and the second edge; and
insert molding with a resin to be the case being prevented from flowing into the opening of the cap nut after the integrating and the bending.
